(19) United States
(12) Patent Application Publication
(10) Pub. No.: US 2008/0093682 A1
(43) Pub. Date: Apr. 24, 2008

(54) Polysilicon levels for silicided structures including MOSFET gate electrodes and 3D devices

(76) Inventors: Liang-Gi Yao, Hsinchu (TW); Jin Ying, Singapore (SG); Hun-Jan Tao, Hsin-Chu (TW); Shih-Chang Chen, Hsin-Chu (TW); Mong-Song Liang, Hsin-Chu (TW)

Correspondence Address: SLATER & MATSIL, L.L.P., 17950 PRESTON ROAD, SUITE 1000, DALLAS, TX, 75252, US

(21) Appl. No.: 11/583,491

(22) Filed: Oct. 18, 2006

(51) Int. Cl. H01L 29/76

(52) U.S. Cl. 257/413

(57) ABSTRACT

Semiconductor structures having a silicided gate electrode and methods of manufacture are provided. A device comprises a first silicided structure formed in a first active region and a second silicided structure formed in a second active region. The two silicided structures have different metal concentrations. A method of forming a silicided device comprises forming a polysilicon structure on the first and second device fabrication regions. Embodiments include replacing a first portion of the polysilicon structure on the first device fabrication region with a metal and replacing a second portion of the polysilicon structure on the second device fabrication region with the metal. Preferably, the second portion is different than the first portion. Embodiments further include reacting the polysilicon structures on the first and second device fabrication regions with the metal to form a silicide.

### CROSS-REFERENCE TO RELATED APPLICATIONS

This application is related to co-pending patent application entitled “Method of Making FUSI Gate and Resulting Structure,” Ser. No. 11/543,410, filed Oct. 5, 2006 (Attorney Docket No. TSM05-0821), which application is incorporated herein by reference.

### TECHNICAL FIELD

This invention relates generally to semiconductor devices, and more particularly to semiconductor devices with gate electrodes formed by silicidation.

### BACKGROUND

Complementary metal oxide semiconductor (CMOS) devices, such as metal oxide semiconductor field-effect transistors (MOSFETs), are commonly used in the fabrication of very large-scale integrated (VLSI) devices. The continuing trend is to reduce the size of the devices and to lower the power consumption requirements. Size reduction of the MOSFETs has enabled the continued improvement in speed performance, density, and cost per unit function of integrated circuits.

FIG. 1 illustrates one type of a MOSFET formed on a substrate 110. The MOSFET generally has source/drain regions 112 and gate electrodes 116. A channel 118 is formed between the source/drain regions 112. The gate electrode 116 is formed on a dielectric layer 120. Spacers 122 are formed on each side of the gate electrode 116, and contact pads or silicide pads 124 are formed on the source/drain regions 112 and the gate electrodes 116. The source/drain regions 112 and/or the contact pads 124 may be raised. Isolation trenches 126 may be used to isolate the MOSFETs from each other or other devices.

The contact pads 124 provide reduced contact resistance and are frequently formed of a metal silicide. Furthermore, the contact pad 124 on the gate electrode 116 is generally formed in the same process steps as the contact pad 124 on the source/drain regions 112, and thus, has the same characteristics. Many times, however, it is desirable that the silicided portions of the source/drain regions 112 exhibit different operating characteristics.

Furthermore, as the size of semiconductor devices are reduced, it is desirable to use a metal gate electrode, such as a fully silicided gate electrode, to further reduce resistance and CET (capacitance effective thickness). Attempts have been made to fabricate a highly conductive gate electrode by performing a silicidation process on the polycrystalline semiconductor gate electrode, which is frequently a polysilicon (poly-Si) material or poly-SiGe material. Generally, the silicidation reaction converts the polycrystalline semiconductor material to a highly conductive silicide. One method of fabricating a semiconductor device having a silicided gate electrode is described in U.S. Pat. No. 6,905,922 entitled, “Dual Fully-Silicided Gate MOSFETs,” which is incorporated herein by reference.

Often, however, a different type of metal is desired or a different amount of silicidation is desired in order to create varying work functions dependent upon the device and its characteristics. Thus, there is a need for silicided structures in which characteristics may be tuned or optimized for a particular application.

### SUMMARY OF THE INVENTION

These and other problems are generally reduced, solved or circumvented, and technical advantages are generally achieved, by embodiments of the present invention, which provides semiconductor methods and devices having silicided gate electrodes.

An embodiment of the invention provides a semiconductor device. The device comprises a semiconductor substrate having first and second active regions. The device includes a first silicided structure formed in the first active region and a second silicided structure formed in the second active region. Preferably, the two silicided structures have different metal concentrations. In an embodiment of the invention, the first and second silicided structures each comprise a transistor gate electrode of a transistor.

In another embodiment of the invention, another device comprises an isolation region formed in a substrate, wherein the isolation region electrically isolates a first active region and a second active region. A first transistor having a fully silicided gate electrode is formed in the first active region.

Yet another embodiment of the invention provides a method of forming a semiconductor device. The method comprises providing a substrate having a first device fabrication region and a second device fabrication region, and forming a polysilicon structure on the first and second device fabrication regions. Embodiments include replacing a first portion of the polysilicon structure on the first device fabrication region with a metal and replacing a second portion of the polysilicon structure on the second device fabrication region with the metal. Preferably, the second portion is different than the first portion. Embodiments further include reacting the polysilicon structures on the first and second device fabrication regions with the metal to form a silicide.

In embodiments of the invention, the device comprises a transistor. The transistor may further include a gate dielectric such as HfSiON, Ta2O5, TiO2, Al2O3, ZrO2, HfO2, Y2O3, La2O3, HfSiOx, HfAlOx, PbTiO3, BaTiO3, SrTiO3, PbZrO3, aluminates and silicates thereof, or combinations thereof. The device may further comprise an isolation structure that separates first and second active regions. Preferably, the silicided structures comprise a silicide of a material such as Ni, Co, Cu, Mo, Ti, Ta, W, Er, Zr, Pt, Yb, or combinations thereof. The substrate may comprise silicon, germanium, silicon germanium, and silicon-on-insulator, or combinations thereof. Devices may further comprise a dielectric layer overlying the first and second silicided structures.

Note that although the term layer is used throughout the specification and in the claims, the resulting features formed using the layer should not be interpreted as only a continuous or uninterrupted feature. As will be clear from reading the specification, the semiconductor layer may be separated into distinct and isolated features (e.g., active regions or device fabrication regions), some or all of which comprise portions of the semiconductor layer.

Additional features and advantages of embodiments of the invention will be described hereinafter, which form the subject of the claims of the invention. It should be appreciated by those skilled in the art that the specific embodiments disclosed might be readily utilized as a basis for modifying or designing other structures or processes for carrying out the purposes of the present invention. It should also be realized by those skilled in the art that such equivalent constructions and variations on the example embodiments described do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is cross-sectional view of a prior art silicided gate electrode;

FIGS. 2a-2b are cross-sectional views of forming a silicided semiconductor structure according an embodiment of the invention; and

FIGS. 3a-5c are cross-sectional views of forming silicided gate electrodes according an alternative embodiments of the invention.

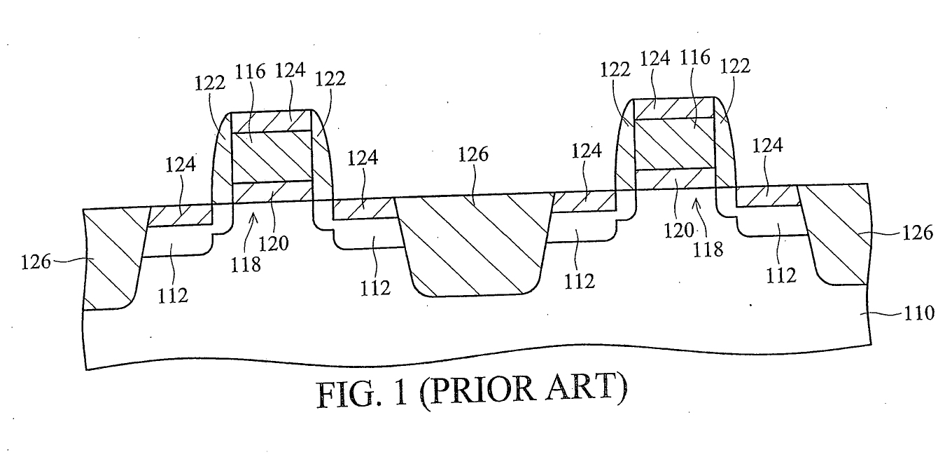

Corresponding numerals and symbols in the different figures generally refer to corresponding parts unless otherwise indicated. The figures are drawn to clearly illustrate the relevant aspects of the preferred embodiments and are not necessarily drawn to scale. To more clearly illustrate certain embodiments, a letter indicating variations of the same structure, material, or process step may follow a figure number.

### DETAILED DESCRIPTION OF ILLUSTRATIVE EMBODIMENTS

The operation and fabrication of the presently preferred embodiments are discussed in detail below. However, the embodiments and examples described herein are not the only applications or uses contemplated for the invention. The various embodiments discussed are merely illustrative of ways to make and use the invention, and do not limit the scope of the invention or the appended claims.

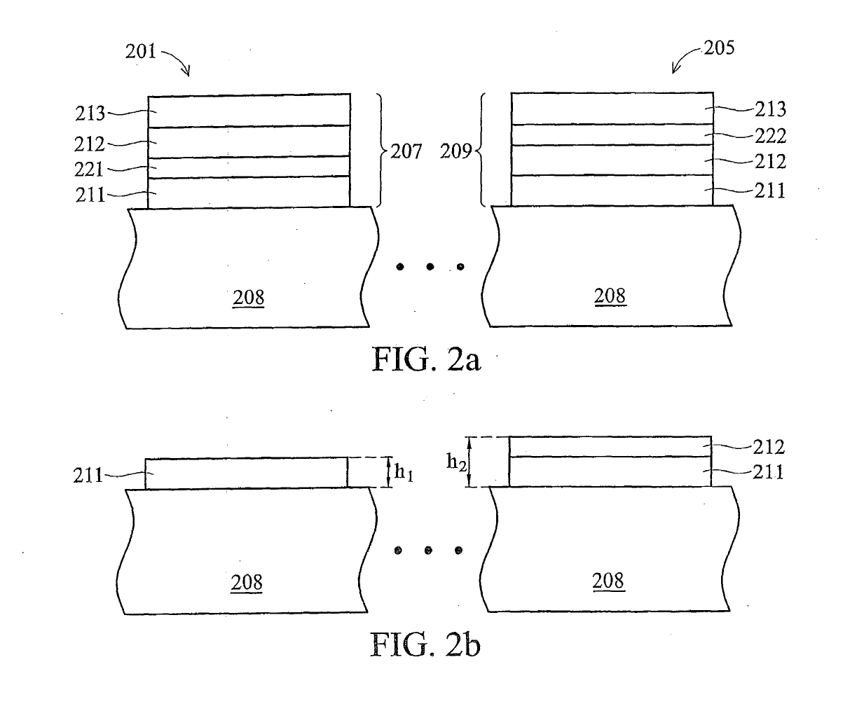

One problem with conventional fully silicided (FUSI) fabrication methods, is that it is difficult to simultaneously control the height of the gate electrode as well as silicide composition. Embodiments of the invention solve this problem through a novel multilevel polysilicon process. Before describing several exemplary embodiments of the invention in detail, a general description of embodiments of the invention is provided in connection with FIGS. 2a-2b.

Generally, embodiments of the invention provide silicided semiconductor structures and methods of forming the structures. FIGS. 2a-2b illustrate a first exemplary embodiment of the invention. Turning now to FIG. 2a, there is illustrated a first device fabrication region 201 and a second device fabrication region 205 in a semiconductor substrate 208. By way of example, the device fabrication regions may comprise suitably doped active areas in a silicon wafer wherein NMOS and PMOS transistors are formed.

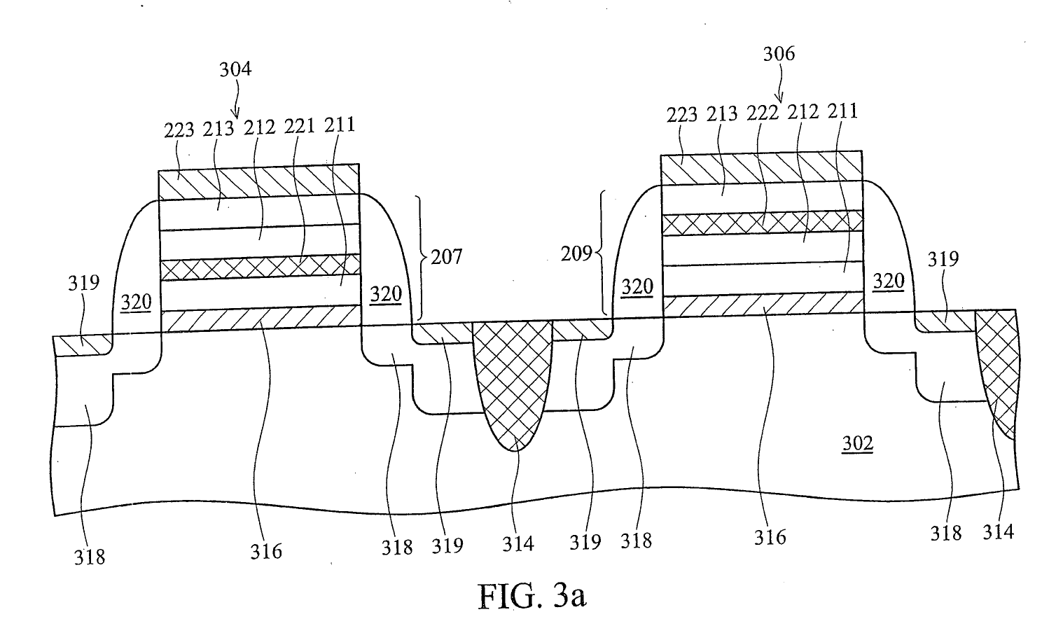

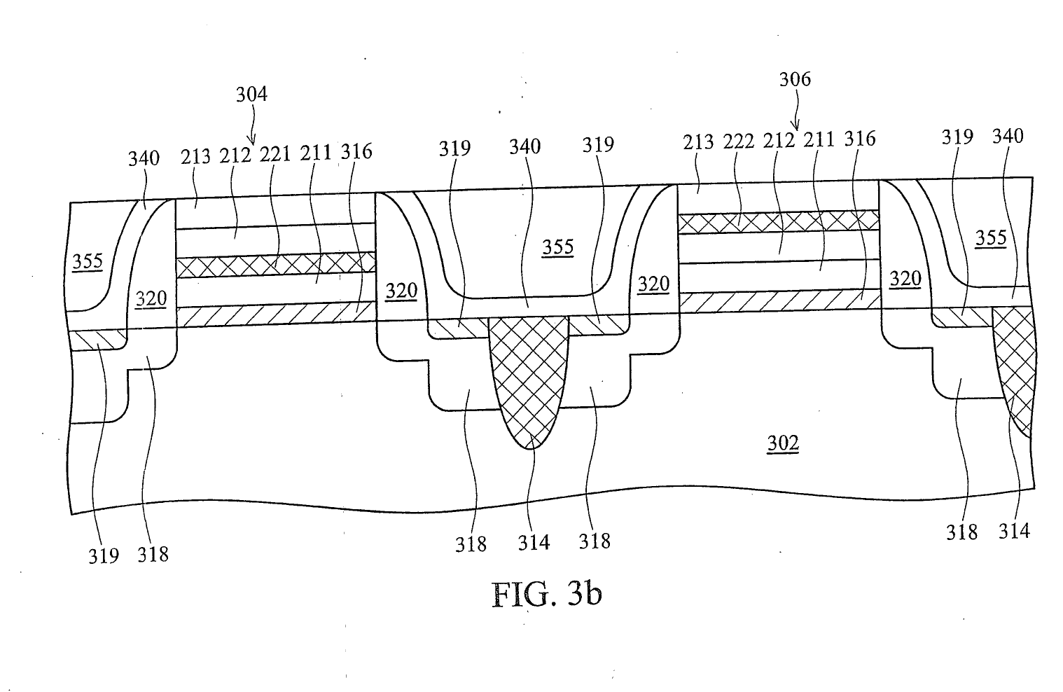

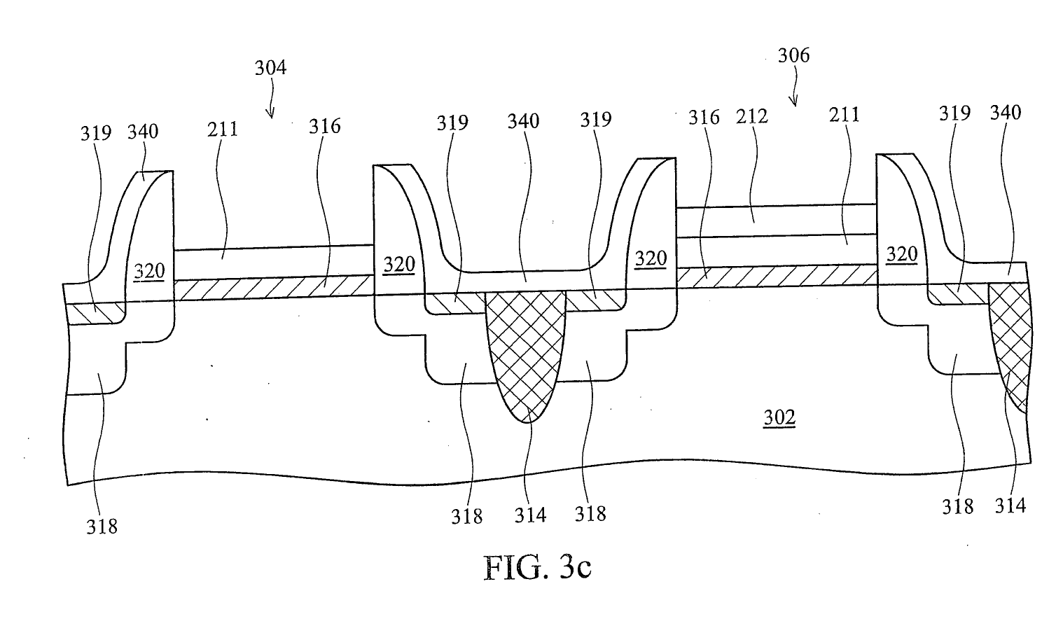

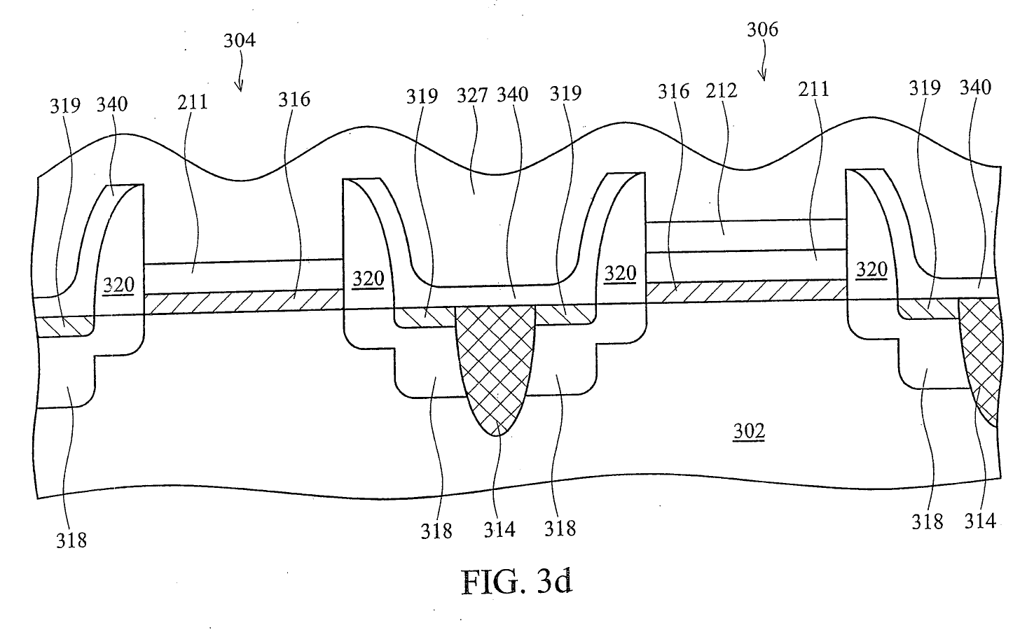

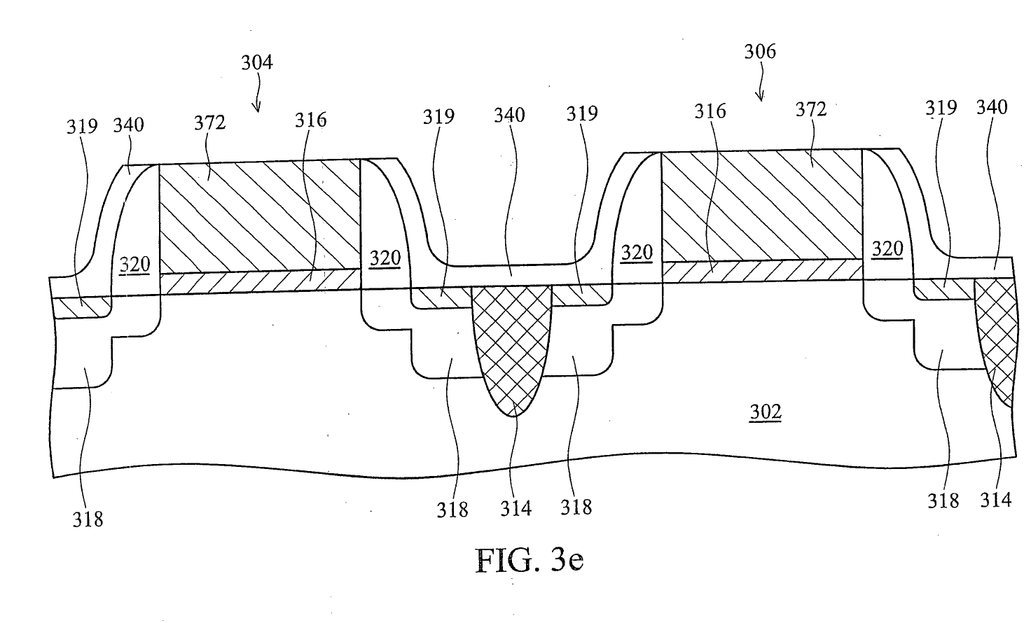

Within the first and second device fabrication regions, 201 and 205, there is formed a first and second semiconductor structure, 207 and 209. Each structure comprises a first polysilicon layer 211 over the substrate 208, a second polysilicon layer 212 over the first polysilicon layer 211, and a third polysilicon layer 213 over the second polysilicon layer 212. The polysilicon layers may be formed and patterned using conventional techniques. Preferably, the first structure 207 further comprises a first ESL 221 between the first and second polysilicon layers, 211 and 212. Likewise, the second structure 209 further comprises a second ESL 222 between the second and third polysilicon layers, 212 and 213. As will be apparent from the below discussion, and particularly with reference to the illustrations of FIG. 3, third polysilicon layer 213 is optional in many embodiments, as it will be removed from both first structure 207 and second structure 209.

The first and second etch stop layers, 221 and 222, preferably comprise a layer containing Si, N, O, or C, and more preferably comprise silicon oxide, silicon nitride or silicon oxynitride. The etch stop layers may be formed, for example, by oxide growth, chemical vapor deposition or physical vapor deposition at a temperature of about 250° C. to about 1000° C. and an ambient of oxygen-containing and/or silicon-containing and/or nitrogen-containing gases. The etch stop layers, 221 and 222, are preferably about 10 Å to about 200 Å thick, but most preferably about 20 Å to about 50 Å thick.

Turning now to FIG. 2b, the multi-layer stack of first structure 207 is etched back to first polysilicon layer 211 and the second structure 209 is etched back to second polysilicon layer 212. These can be readily and simultaneously accomplished as follows (with reference back to FIG. 2a). Using an appropriate etch process that removes polysilicon, polysilicon layers 213 and 212 of first structure 207 are removed in a single etch step. At the same time, polysilicon layer 213 is etched from the second structure 209 but the etching stops on etch stop layer 222. Then, again using an appropriate etch process, first etch stop material 221 of first structure 207 and second etch stop material 222 of second structure 209 can be simultaneously etched. Because this second etch process is selective to the etch stop layer material, etching will stop on second polysilicon layer 212 (in the case of second structure 209) and on first polysilicon layer 211 (in the case of first structure 207). The resulting structure is a so-called 3-D polysilicon gate structure where simultaneously formed structures 207 and 209 have different heights.

Turning now to FIGS. 3a to 3e, there is illustrated an alternative embodiment of the invention in a more specific context, namely: silicided gate electrodes in MOSFET devices. Exemplary structures and methods are provided below for fabricating a metal oxide semiconductor field effect transistor (MOSFET) according to embodiments of the invention. Although the exemplary embodiments are described as a series of steps, it will be appreciated that this is for illustration and not for the purpose of limitation. For example, some steps may occur in a different order than illustrated yet remain within the scope of the invention. In addition, not all illustrated steps may be required to implement the present invention. Furthermore, the structures and methods according to embodiments of the invention may be implemented in association with the fabrication or processing of other semiconductor structures not illustrated.

Turning now to FIG. 3a, there is illustrated a substrate 302 having a first transistor 304 and a second transistor 306 formed thereon. More accurately, FIG. 3a illustrates an intermediate structure from which transistor 304 and transistor 306 will be formed after further processing steps. For purposes of convenience these and other intermediate structures will be referred to as transistor 304 and transistor 306, respectively. The first transistor 304 comprises a first gate electrode stack 307. The first gate electrode stack 307 is formed according to embodiments provided above, and it comprises the first polysilicon layer 211 over the substrate 302, the first ESL 221 on the first polysilicon layer 211, the second polysilicon layer 212 on the first ESL 221, and the third polysilicon layer 213 on the second polysilicon layer 212. The second transistor 306 comprises a second gate electrode stack 309. The second gate electrode stack 309 is formed according to embodiments provided above, and it comprises the first polysilicon layer 211 over the substrate 302, the second polysilicon layer 212 on the first polysilicon layer 211, the second ESL 222 on the second polysilicon layer 212, and the third polysilicon layer 213 on the second ESL 222. As was explained above, polysilicon layer 213 may be optional. It is believed, however, that polysilicon layer 213 provides an advantage of increasing the thickness of the dummy polysilicon gate stack during subsequent process steps, which will be explained below. The polysilicon layers and etch stop layers may be formed and patterned using methods known in the art.

Each of the first transistor 304 and the second transistor 306 further includes, source/drain regions 318 having source/drain silicide regions 319, and a gate dielectric layer 316 formed between the first and second gate electrode stacks, 307 and 309 respectively, and the substrate 302. Spacers 320 are formed along sides of the gate electrode stacks. Embodiments may optionally include using a different sealed layer in the first spacer layer to protect the spacer if necessary during the ESL removal step. Isolation structures 314 isolate the first transistor 304 and the second transistor 306 from each other and from other structures.

The substrate 302 is preferably a bulk semiconductor substrate, which is typically doped to a concentration in the range of 10¹⁵ cm⁻³ to 10¹⁸ cm⁻³, or a semiconductor-on-insulator (SOI) wafer. Other materials, such as germanium, quartz, sapphire, glass, and Si—Ge epi could alternatively be used for the substrate 302 or part of the substrate 302. The structure shown in FIG. 3a may comprise either NMOS structures, PMOS structures, or a combination thereof, for example as in a CMOS device. In fact, in a typical embodiment, the arrangement shown as stack 307 would likely be used to form an NMOS device, whereas stack 309 would likely be used to form a PMOS device. This is because the work function of the respective resulting gate can be tuned by adjusting the subsequently formed silicide. As discussed above, the composition of the resulting silicide material will be different for stack 307 and stack 309. One skilled in the art can select the appropriate combination of polysilicon layers and silicidation metal to achieve the desired work function for the resulting gate structure.

The gate dielectric layer 316 may comprise silicon oxide, which has a dielectric constant of about 3.9. The gate dielectric layer 316 may also comprise materials having a dielectric constant greater than silicon oxide. This class of dielectrics is generally referred to as high-k dielectrics. Suitable high-k dielectrics include Ta2O5, TiO2, Al2O3, ZrO2, HfO2, Y2O3, LaO3, and their aluminates and silicates. Other high-k dielectrics may include HfSiOX, HfAlOX, ZrO2, Al2O3, barium strontium compounds such as BST, lead based compounds such as PbTiO3, similar compounds such as BaTiO3, SrTiO3, PbZrO3, PST, PZN, PZT, PMN, metal oxides, metal silicates, metal nitrides, combinations and multiple layers of these. In embodiments of the invention, the high-k dielectric layer 316 is typically about 1 Å to about 100 Å thick, preferably less than about 50 Å. A non-plasma process is preferably used to avoid forming traps generated by plasma-damaged surfaces. Preferred processes include evaporation-deposition, sputtering, CVD, PVD, MOCVD, and ALD.

Turning now to FIG. 3b, there is the intermediate device of FIG. 3a after forming thereon a protection layer 340 and a masking layer such as a photoresist layer 355. Protection layer 340 is preferably an oxide or nitride (e.g., silicon oxide, silicon nitride, silicon oxynitride) that is conformally deposited over the source/drain regions and over the polysilicon stacks. Photoresist layer 335 is next deposited over the structure above the top of the polysilicon stacks. As shown in FIG. 3b, photoresist layer 335 is etched back and the portions of protection layer 340 overlying the polysilicon stacks is also etched back to expose polysilicon layer 213. This etch back is illustratively accomplished in a two-step approach. For instance, a first ashing step could be employed to lower the top surface of photoresist layer 335 to the top of protection layer 340. A second wet etch step could then be employed to remove the exposed portion of protection layer 340. Note that the remaining photoresist layer 335 protects those portions of protection layer 340 overlying the source and drain regions, so that portions are not removed during the wet etch step. Note that hard mask layer 223, if it still remains on the top of the respective polysilicon stacks, is also removed during the wet etch process. Hard mask layer 223 may be a remnant of the gate stack patterning process. After etching back protection layer 340 (and hard mask layer 223, if needed), photoresist layer 335 can be removed.

Next, as shown in FIG. 3c, a first recess is formed in the first polysilicon stack 307 (identified in FIG. 3a), and a second recess is formed in the second polysilicon stack 309 (also identified in FIG. 3a). Forming the first recess may comprise removing the removing polysilicon layers 213 and 212 (FIG. 3b) in a first etch step and stopping on etch stop layer 221 (FIG. 3b). Polysilicon layer 213 is simultaneously removed from the second polysilicon stack 309 at this time, but the etch will stop on etch stop layer 222 (FIG. 3b), which protects the polysilicon layer 212 (FIG. 3b) in stack 309. Etch stop layers 221 and 222 can then be simultaneously etched away using an appropriate etch chemistry. Note that, because of the selection of appropriate materials for etch stop layers 221 and 222, with high etch selectivity relative to polysilicon, underlying polysilicon layer 211 (for stack 307) and underlying polysilicon layer 212 (for stack 309) will not be etched (or will only be minimally etched assuming some level of over-etching) during the removal of etch stop layers 221 and 222. Removing the etch stop and polysilicon layers may comprise etching with H2SO4, HCl, H2O2, NH4OH, HF, for example. Dry etching may also be used to remove the polysilicon layers. The resulting structure is illustrated in FIG. 3c, wherein stack 307 has only a single polysilicon layer remaining (211) and stack 309 has two polysilicon layers remaining (211 and 212).

Note that sidewall spacers 320 might be attacked during the removal of etch stop layers 221 and 222 (assuming that similar materials are employed for the spacers and the etch stop layers). Optionally, a sidewall seal layer could be formed on the sidewall of the respective polysilicon stacks prior to formation of the sidewall spacers. As an example, assuming sidewall spacers 320 and etch stop layers 221 and 222 are oxides, a thin nitride seal layer could be formed on the sidewalls of the polysilicon stacks prior to the formation of the sidewall spacers. This nitride layer will protect sidewall spacers 320 from being attacked during the removal of etch stop layers 221 and 222. First ESL 221 (FIG. 3B) and the second and third polycrystalline layers 212 and 213 (FIG. 3a).

Next the respective recess of the first and second transistors, 304 and 306, are filled with a metal 327 to form silicides after subsequent processes, as shown in FIG. 3d. The metal layer 327 may be formed, for example, by conventional deposition techniques such as, for example, evaporation, sputter deposition, or chemical vapor deposition (CVD). The layer is preferably about 10 Å to about 700 Å in thickness, but most preferably about 10 Å to about 500 Å in thickness. The metal layer 327 may be a single layer or a plurality of layers. It may comprise any silicidation metal such as, for example, nickel, cobalt, copper, molybdenum, titanium, tantalum, tungsten, erbium, zirconium, platinum, Yb or a combination thereof.

The structure of FIG. 3d is next silicided to react the metal layer 327 and the respective underlying polysilicon layers to form a first and second silicided structure, 371 and 372, as shown in FIG. 3e. The composition of the silicided structure is dependent upon the relative number of polysilicon and metal layers in pre-silicided structure. Note that in this illustrative embodiment, resulting silicide structure 371 has the same height as resulting silicide structure 372. The reason for this is as follows. Assume that metal layer 327 is nickel (Ni). Silicide structure 371, which was formed from the silicidation of metal layer 327 and only one polysilicon layer 211, will be relatively nickel rich. As is known, a nickel rich silicide (e.g., Ni2Si) film has a thickness of roughly 2.2 times the thickness of the original polysilicon film (211) from which it is formed. By contrast, silicide structure 372, which was formed from the silicidation of two polysilicon layers (211 and 212), is a relatively nickel poor, so-called nickel-less, film. By contrast to nickel rich film 371, nickel, poor silicide film 372 has a thickness of only about 1.2 times the thickness of the original polysilicon layer(s) from which it was formed. This is why the silicide height is relatively the same, even though structure 371 was formed from two layers (metal 327 and polysilicon layer 211) and structure 372 was formed from three layers (metal 327, polysilicon layer 211, and polysilicon layer 212). While nickel is described in the illustrative embodiments, this teaching applies equally to other metals as well, although the specific thickness ratios will likely vary depending upon the materials selected.

The silicidation process 330 may be performed by annealing at a temperature of about 200° C. to about 1100° C. for about 0.1 seconds to about 300 seconds in an inert ambient preferably comprising nitrogen, but most preferably at a temperature of 250° C. to about 750° C. for about 1 second to about 200 seconds. Optionally, an additional RTA process may be performed to further change the phase to a low-resistivity silicide. In particular, it has been found that CoSi2 and TiSi2, for example, benefit from an additional RTA process performed at a temperature from about 300° C. to about 1100° C. for 0.1 seconds to about 300 seconds, and more preferably, about 750° C. to about 1000° C. Unreacted metal of 327 layer during silicidation, if any, may be removed by e.g., a wet cleaning process, and the resulting structure is shown in FIG. 3e.

As described above, the silicide metal 327 may be a single layer or a plurality of layers and may comprise any silicidation metal such as, for example, nickel, cobalt, copper, molybdenum, titanium, tantalum, tungsten, erbium, zirconium, platinum, or a combination thereof.

Embodiments of the invention may be combined with conventional methods used to form a silicide contact area for the source/drain regions 318. Gate electrodes and contact areas may be silicided concurrently or separately. In the embodiment being illustrated, silicided gate electrodes are formed simultaneously by different poly heights as described above. Such a process allows each gate electrode to be independently optimized. for its particular function and desired operating characteristics, such as varying the work function of the transistor.

After forming the silicided gate electrodes, the intermediate semiconductor device is completed according to conventional fabrication methods. For instance, a contact etch stop layer 344, preferably silicon nitride, is formed over the surface, followed by formation of an interlayer-dielectric material 346, as is well known in the art.

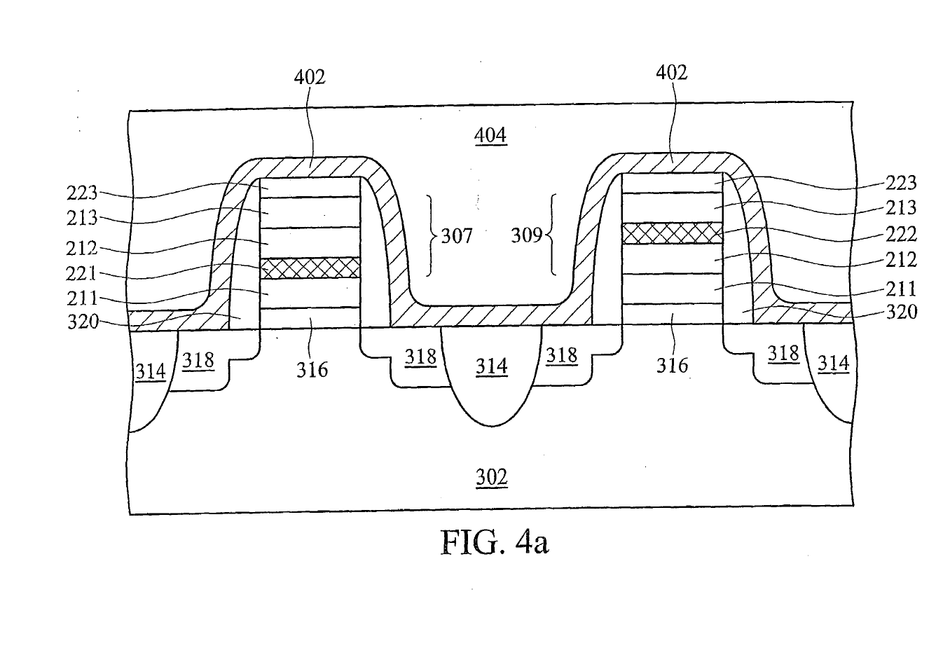

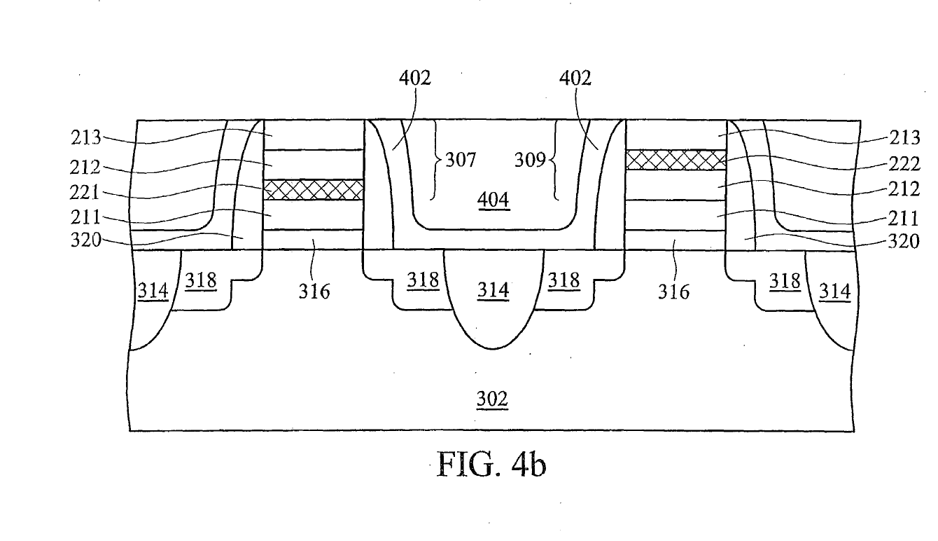

Another illustrative embodiment is illustrated with reference to FIGS. 4a and 4b. Beginning with the structure illustrated in FIG. 3a, a contact etch stop layer (CESL) 402 is deposited on the device, as shown in FIG. 4a. CESL 402 is illustratively silicon nitride deposited by CVD or PECVD. Inter-layer dielectric (ILD) 404 is deposited over the device, also as shown in FIG. 4a. ILD 404 is illustratively spun-on-glass (SOG), high density plasma oxide, and the like.

ILD layer 404 is then subjected to a chemical mechanical polish (CMP) process in which the top surface of ILD layer is planarized and lowered. CMP processing continues when the top surface of CESL 402 is reached and the portions of CESL 402 overlying gate stacks 307 and 309 are removed as well. Likewise, CMP processing continues with the removal of hard mask layer 223, assuming same is still extant on the respective polysilicon stacks. After CMP processing, the resulting structure is illustrated in FIG. 4b, wherein polysilicon layer 213 is exposed on the respective polysilicon stacks 307 and 309. Processing can then continue much as described above with reference to FIGS. 3c through 3e but with ILD layer 404 providing the role of protecting source and drain regions. Polysilicon layers 213 and 212 (stack 307) or 213 (stack 309) are removed, followed by removal of etch stop layers 221 (stack 307) and 222 (stack 309). Metal layer 327 is next deposited on the respective stacks and reacted with the underlying polysilicon layers 211 (stack 307) or 212 (stack 309). Excess, unreacted metal is then removed, and processing can continue with the formation of additional ILD material, formation of contacts in the ILD layer, and connection with subsequently formed metal interconnects, as are known in the art.

The above described illustrative embodiments result in gate stacks of different silicide formation, yet similar final gate height. This is an advantageous feature that allows for work function tuning between, e.g., PMOS and NMOS devices while simplifying integration with the overall CMOS process flow (e.g, similar step height, similar conformal film coverage, and the like). In an alternative embodiment, however, the teachings of the present invention can be extended to provide for gates having different gate heights in the same integrated circuit.

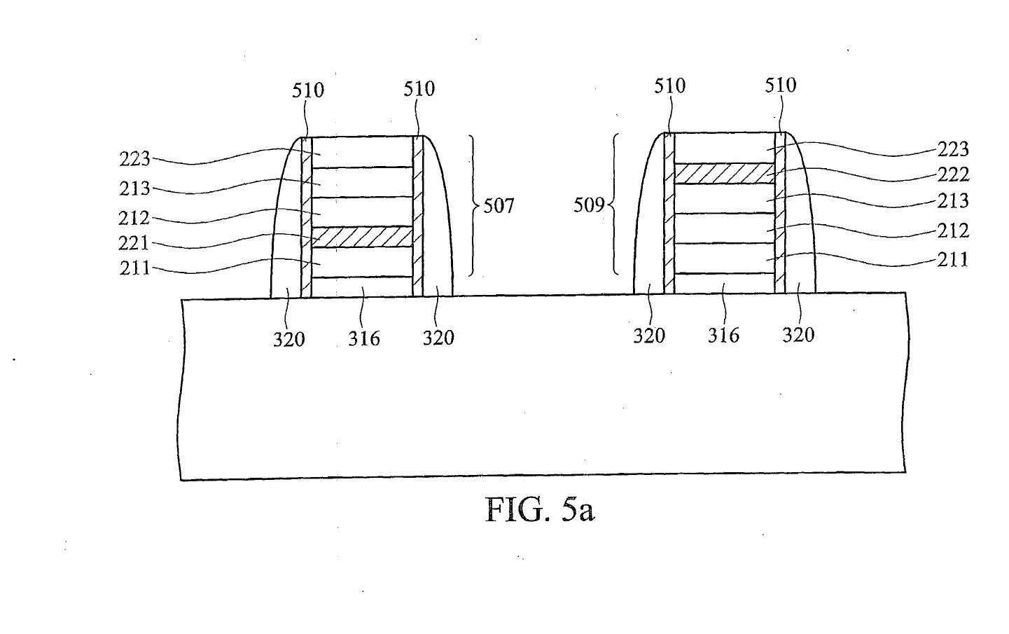

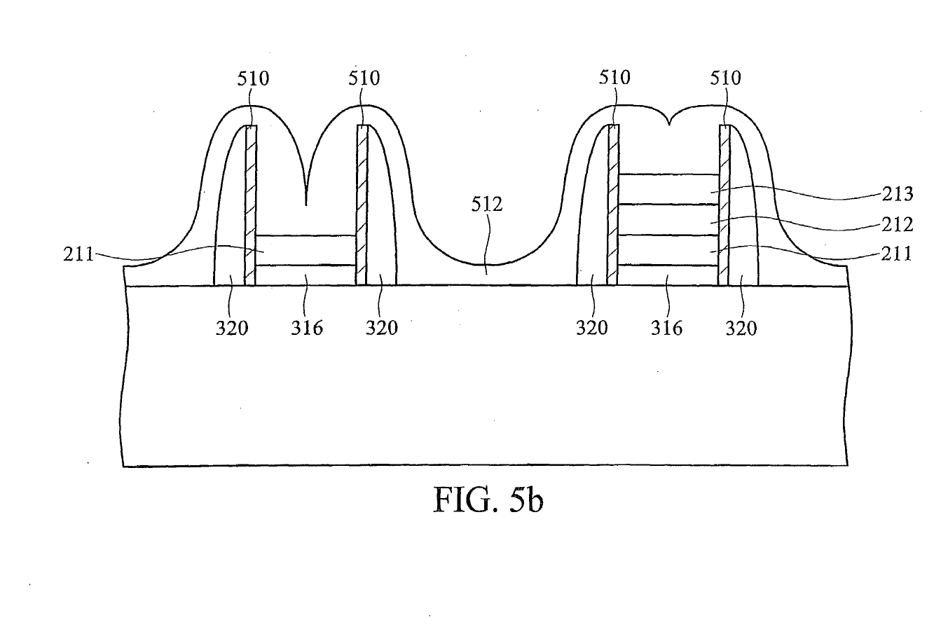

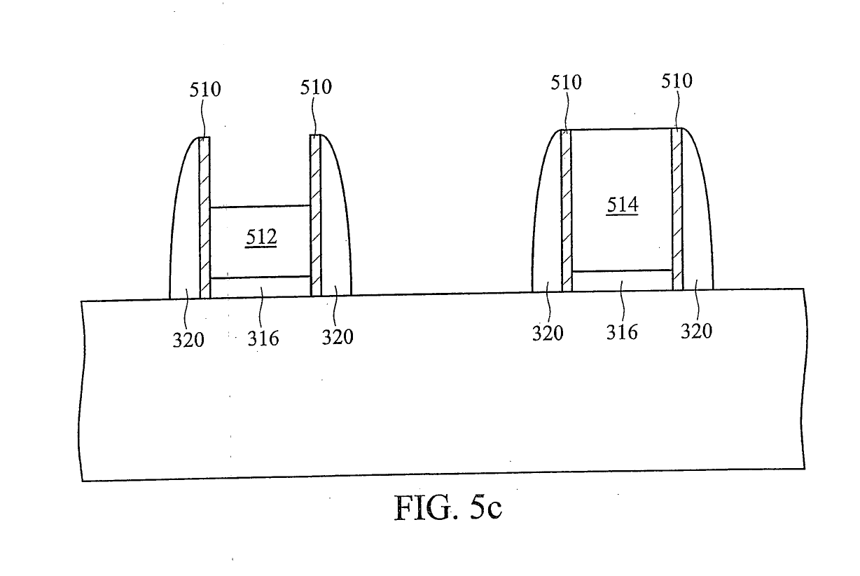

One such embodiment of a different gate height structure is shown in FIGS. 5a through 5c. Beginning with FIG. 5a, an illustrative structure is shown in which a first polysilicon stack 507 comprises (beginning at the bottom) a gate dielectric 316, first polysilicon layer 211, first etch stop layer 221, second polysilicon layer 212, third polysilicon layer 213, and finally hard mask layer 223. As discussed above, hard mask layer 223 is employed in patterning the respective gate stacks 507, 509, and may be removed at any subsequent step of processing. Also shown in FIG. 5a are optional sidewall seal spacers or sidewall seal liners 510. These sidewall seal liners protect sidewall spacers 320 (also optional) during removal of etch stop layers 221 and/or 222. Note that all three polysilicon layers (211, 212, 213) of stack 509 are below etch stop layer 222. This means that these three layers are preserved (not removed) during removal of layer 213 of stack 507. The resulting structure, after removal of the polysilicon layers, if any, is shown in FIG. 5b.

Also shown in FIG. 5b is metal layer 512 which has been deposited over the structure. As in the previously described embodiments, metal layer is illustratively nickel, but may alternatively be cobalt, copper, molybdenum, titanium, tantalum, tungsten, erbium, zirconium, platinum, Yb or a combination thereof.

Next, and as shown in FIG. 5c, metal layer 512 is reacted with the underlying polysilicon layer(s) to form fully silicided structures 512, 514, respectively, having different gate heights. Numerous variations will be apparent to one skilled in the art with the benefit of the teachings contained herein and routine experimentation to obtain various fully silicided structures, including gate structures, of varying height. In a particularly advantageous embodiment, the ratio of the first fully silicided gate height to the second fully silicided gate height is not larger than ½. While the illustrated gate structures provide for different silicide composition and different heights, it is also within the contemplated scope of the invention that structures having the same silicide composition, but differing gate heights. In yet another embodiment, one or more gate structures could be manufactured with differing gate heights without performing a silicidation step.

Although embodiments of the present invention and their advantages have been described in detail, it should be understood that various changes, substitutions and alterations can be made herein without departing from the spirit and scope of the invention as defined by the appended claims (e.g., 3D devices such as FinFET). For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device comprising:
a semiconductor substrate comprising a first active region and a second active region; a first silicided structure formed in the first active region, wherein the first silicided structure has a first metal concentration; and
a second silicided structure formed in the second active region, wherein the second silicided structure has a second metal concentration, the second metal concentration not equal to the first metal concentration.

2. The semiconductor chip of claim 1, wherein the first and second silicided structures each comprise a transistor gate electrode of a transistor.

3. The semiconductor chip of claim 2, wherein the transistor further comprises a gate dielectric selected from the group consisting essentially of SiO2, SiON, HfSiON, Ta2O5, TiO2, Al2O3, ZrO2, HfO2, Y2O3, La2O3, HfSiOX, HfAlOX, PbTiO3, BaTiO3, SrTiO3, PbZOr3, aluminates and silicates thereof, and combinations thereof.

4. The semiconductor device of claim 1, wherein the first and second active regions are separated by an isolation structure.

5. The semiconductor device of claim 1, wherein the first and second silicided structures each comprise a silicide of a material selected from the group consisting essentially of Ni, Co, Cu, Mo, Ti, Ta, W, Er, Zr, Pt, Yb, Hf, Al, Zn and combinations thereof.

6. The semiconductor device of claim 1, wherein the substrate comprises a semiconductor substrate selected from the group consisting essentially of silicon, germanium, silicon germanium, and silicon-on-insulator.

7. The semiconductor device of claim 1, further comprising a dielectric layer overlying the first and second silicided structures.

8. A semiconductor device comprising:
an isolation region formed in a substrate, wherein the isolation region electrically isolates a first active region and a second active region;
a first transistor formed in the first active region, the first transistor comprising a first fully silicided gate electrode; and
a second transistor formed in the second active region, the second transistor comprising a second fully silicided gate electrode, wherein the height of the second gate electrode not equal to the height of the first gate electrode.

9. The semiconductor device of claim 8, wherein the first fully silicided gate electrode and the second silicided gate electrode each comprise a silicide of a material selected from the group consisting essentially of Ni, Co, Cu, Mo, Ti, Ta, W, Er, Zr, Pt, Yb, Hf, Al, Zn, and combinations thereof.

10. The semiconductor device of claim 8, wherein an atomic ratio of metal to silicon in the first fully silicided gate electrode is greater than about 0.6.

11. The semiconductor device of claim 8, wherein an atomic ratio of metal to silicon in the second silicided gate electrode is less than about 0.6.

12. The method of claim 8, wherein a height of the silicided gate electrodes is substantially the same.

13. The semiconductor chip of claim 8, wherein the first and second transistors further comprise a gate dielectric material selected from the group consisting essentially of SiO2, SiON, HfSiON, Ta2O5, TiO2, Al2O3, ZrO2, HfO2, Y2O3, La2O3, HfSiOx, HfAlOx, PbTiO3, BaTiO3, SrTiO3, PbZrO3, aluminates and silicates thereof, and combinations thereof.

14. The semiconductor device of claim 8, wherein the first and second transistors are separated by an isolation structure.

15. The semiconductor device of claim 8, wherein the substrate comprises a semiconductor substrate selected from the group consisting essentially of silicon, germanium, silicon germanium, SiC, III-V compounds, and silicon-on-insulator.

16. A semiconductor device comprising:
a substrate;
a first transistor having a first fully silicided gate overlying the substrate and having a first height; and
a second transistor having a second fully silicided gate overlying the substrate and having a second height, the height ratio of the first height to the second height being not larger than ½.

17. The semiconductor device of claim 16 wherein said first fully silicided gate comprises nickel silicide.

18. The semiconductor device of claim 16 wherein said first transistor is an NFET.

19. The semiconductor device of claim 16 wherein:
said first transistor includes;
a first source region;
a first drain region;
a first channel region between the first source region and first drain region;
a first gate dielectric overlying the first channel region; and
said second transistor includes;
a second source region;
a second drain region;
a second channel region between the second source region and second drain region;
a second gate dielectric overlying the second channel region.

20. The semiconductor device of claim 16 wherein said first transistor and said second transistor are electrically connected in a CMOS configuration.
